(19) United States
(12) Patent Application Publication
(10) Pub. No.: US 2012/0003397 A1
(43) Pub. Date: Jan. 5, 2012

(54) METHOD FOR DEPOSITING NANOPARTICLES ON A SUPPORT

(75) Inventors: François Reniers, Bruxelles (BE); Frédéric Demoisson, Dijon (FR); Jean-Jacques Pireaux, Jambes (BE)

(73) Assignee: Universite LIbre de Bruxelles, Bruxelles (BE)

(21) Appl. No.: 12/673,437

(22) PCT Filed: Aug. 14, 2008
(86) PCT No.: PCT/EP2008/060676

§ 371 Date: Sep. 16, 2011

(30) Foreign Application Priority Data
Aug. 14, 2007 (EP) 07114344.0
Feb. 14, 2008 (EP) 08151463.0

(51) Int. Cl. C23C 16/50; C23C 16/40; C23C 16/06

(52) U.S. Cl. 427/576; 427/569

(57) ABSTRACT

A method for depositing nanoparticles on a support includes taking a colloidal solution of nanoparticles. The method also includes nebulizing the colloidal solution of nanoparticles on a surface of the support in an atmospheric plasma.

### OBJECT OF THE INVENTION

The present invention relates to a method for depositing and attaching nanoparticles on any support.

### STATE OF THE ART

It is generally recognized that the term of [symbol] nanoparticle [symbol] describes an aggregate of small molecules, or an assembly of a few tens to a few thousand of atoms, forming a particle, the dimensions of which are of the order of one nanometer, i.e. smaller than 1,000 nm (1μ), preferably less than 100 nm. Because of their size, these particles have particular physical, electrical, chemical and magnetic properties and impart to the supports on which they are applied, novel physical, electrical, chemical, magnetic and mechanical properties.

Nanoparticles are of an increasing interest because of their involvement in the development of many devices used in very different fields, such as for example the detection of biological or chemical compounds, the detection of gases or chemical vapors, the elaboration of fuel cells or of devices for storing hydrogen, the making of electronic or optical nanostructures, of novel chemical catalysts, of bio-sensors or so-called smart coatings, such as self-cleaning coatings or which have a particular biological activity, for example an anti-bacterial activity.

There exist many techniques with which nanoparticles of different nature may be deposited on various supports. There exist solution chemistry methods such as those described for example in the article [symbol] Deposition of PbS particles from a nonaqueous chemical bath at room temperature [symbol] of T. Chaudhuri et al. Materials Letters (2005), (17) pp 2191-2193, and in the article [symbol] Deposition of gold nanoparticles on silica spheres by electroless metal plating technique [symbol] of Y. Kobayashi et al., Journal of Colloid and Interface Science (2005), 283 (2) pp 601-604.

There also exist electrochemistry methods as for example those described in the article [symbol] Deposition of clusters and nanoparticles onto boron-doped diamond electrodes for electrocatalysis [symbol] of G. Sine et al., Journal of Applied Electrochemistry, (2006) 36 (8) pp 847-862, and in the article [symbol] Deposition of platinum nanoparticles on organic functionalized carbon nanotubes grown in situ on carbon paper for fuel cell [symbol] of M. Waje et al., Nanotechnology (2005), 16 (7) pp 395-400.

These may also be vacuum deposition techniques involving a plasma as in particular described in the article [symbol] Platinum nanoparticles interaction with chemically modified highly oriented pyrolytic graphite surfaces [symbol] of D. Yang et al., Chemistry of materials (2006) 18 (7) pp 1811-1816, and in the article [symbol] Au nanoparticles supported on HOPG: An XPS characterization [symbol] , of D. Barreca et al. Surface Science Spectra (2005) 10 pp 164-169.

These techniques have many drawbacks, which may for example be problems related to the reproducibility of the method used, problems of distribution, homogeneity and regularity of the deposition of nanoparticles. These techniques are also complex to apply. Generally, they are expensive, because, inter alia, of the necessity of generating a vacuum, even a partial vacuum, and they are difficult to apply on an industrial scale. Further the deposition of nanoparticles usually comprises a step for activating the support, which, in the techniques described earlier, requires preliminary treatment which is very often complex and which may take several hours or even days.

Furthermore, all these techniques pose environmental problems, for solution chemistry as well as electrochemistry, notably because of the use of solvents and chemical reagents which pollute, and problems of large energy consumption, as regards vacuum techniques using a plasma.

In particular, document WO2007/122256 describes the deposition of nanoporous layers by projecting a colloidal solution in a thermal plasma jet, a plasma for which the neutral species, the ionized species and the electrons have a same temperature. In this document, it is specified that the particles of the colloidal solution are at least partly melted in order to be able to adhere to the substrate. In particular, the plasma jet described has a gas temperature comprised between 5,000° K. to 15,000° K. A non-negligible thermal effect will therefore be noted both on the substrate and on the particles of the sol.

### OBJECTS OF THE INVENTION

The present invention proposes a method for depositing nanoparticles on a support which does not have the drawbacks of the state of the art.

The present invention proposes a rapid, inexpensive method and easy to apply.

The present invention also proposes a minimization of the heat stresses both on the substrate and on the nanoparticles.

The present invention also proposes a deposition method which improves homogeneity of the deposit, and more particularly the dispersion of the nanoparticles on the substrate.

### SUMMARY OF THE INVENTION

The present invention discloses a method using a colloidal solution (or suspension) of nanoparticles for depositing nanoparticles on a support, and using atmospheric plasma for depositing nanoparticles on a support.

The present invention relates to a method for depositing nanoparticles on a support comprising the following steps:
taking a colloidal solution (or suspension) of nanoparticles and,
nebulizing said colloidal solution (or suspension) of nanoparticles on a surface of said support in an atmospheric plasma.

By [symbol] nanoparticle [symbol] is meant an aggregate of small molecules, or an assembly of a few hundred to a few thousand atoms, forming a particle, for which the dimensions are of the order of one nanometer, generally smaller than 100 nm.

By [symbol] colloidal solution [symbol] is meant a homogeneous suspension of particles in which the solvent is a liquid and the solute a solid homogeneously disseminated as very fine particles. Colloidal solutions may take various forms, a liquid, gel, or slurry. Colloidal solutions are intermediate between suspensions, which are heterogeneous media comprising microscopic particles dispersed in a liquid, and true solutions, in which the solute(s) is (are) in the state of molecular division in the solvent. Also, in the liquid form, the colloidal solutions are sometimes called [symbol] sols [symbol] .

In a preferred embodiment of the present invention, the atmospheric plasma is an atmospheric non-thermal plasma.

By [symbol] non-thermal plasma [symbol] or [symbol] cold plasma [symbol] is meant a partly or totally ionized gas which comprises electrons, (molecular or atomic) ions, atoms or molecules, and radicals, out of thermodynamic equilibrium, the electron temperature of which (a temperature of several thousand or several tens of thousands of Kelvins) is significantly higher than that of the ions and of the neutral particles (a temperature close to room temperature up to a few hundred Kelvins.

By [symbol] atmospheric plasma [symbol] or, [symbol] atmospheric non-thermal plasma [symbol] or further [symbol] atmospheric cold plasma [symbol] is meant a partly or totally ionized gas which comprises electrons, (molecular or atomic) ions, atoms or molecules, and radicals, out of the thermodynamic equilibrium, the electron temperature of which is significantly higher than that of the ions and of the neutral particles (the temperatures are similar to those described for a [symbol] cold plasma [symbol] ), and for which the pressure is comprised between about 1 mbar and about 1,200 mbars, preferably between about 800 and about 1,200 mbars.

According to a particular embodiment of the invention, the method includes one or more of the following characteristics:
the plasma comprises a plasmagenic gas and the macroscopic temperature of said plasmagenic gas in said plasma may vary between about −20° C. and about 600° C., preferably between −10° C. and about 400° C. and preferably between room temperature and about 400° C.;
the method further comprises a step for activating the surface of the support by submitting said surface of said support to atmospheric plasma;
the activation of the surface of the support and the nebulization of the colloidal solution are concomitant;
the activation of the surface of the support is preceded with a step for cleaning said surface of said support;
the nebulization of the colloidal solution of nanoparticles is accomplished in the discharge area or the post-discharge area of the atmospheric plasma;
the plasma is generated by an atmospheric plasma torch;
the nebulization of the colloidal solution of nanoparticles is accomplished in a direction substantially parallel to the surface of the support;
the nanoparticles are nanoparticles of a metal, of a metal oxide, of a metal alloy or of a mixture thereof;
the nanoparticles are nanoparticles of at least one transition metal, of its corresponding oxide, of an alloy of transition metals or of a mixture thereof;
the nanoparticles are selected from the group formed by magnesium (Mg), strontium (Sr), titanium (Ti), zirconium (Zr), lanthanum (La), vanadium (V), niobium (Nb), tantalum (Ta), chromium (Cr), molybdenum (Mo), tungsten (W), manganese (Mn), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), aluminium (Al), indium (In), tin (Sn), lead (Pb), the corresponding oxides thereof, or an alloy of these metals;
the nanoparticles are selected from the group formed by titanium dioxide (titania (TiO₂)), copper oxide (CuO), ferrous oxide (FeO), ferric oxide (Fe₂O₃), iron oxide (Fe₂O₄), iridium dioxide (IrO₂), zirconium dioxide (ZrO₂), aluminium oxide (Al₂O₂);
the nanoparticles are selected from the group formed by a gold/platinum (AuPt), platinum/ruthenium (PtRu), cadmium/sulfur (CdS), or lead/sulfur (PbS) alloy;
the support is a solid support, a gel or nanostructured material;
the support is selected from the group formed by a carbonaceous support, carbon nanotubes, metal, metal alloy, metal oxide, zeolite, semiconductor, polymer, glass and/or ceramic;
the support is silica, carbon, titanium, alumina, or multi-walled carbon nanotubes;
the atmospheric plasma is generated from a plasmagenic gas selected from the group formed by argon, helium, nitrogen, hydrogen, oxygen, carbon dioxide, air or a mixture thereof;

In a preferred embodiment of the present invention, the colloidal solution comprises a surfactant.

By [symbol] surfactant [symbol] , [symbol] tenside [symbol] or [symbol] surface agent [symbol] is meant a compound modifying the surface tension between two surfaces. Surfactant compounds are amphiphilic molecules, i.e. they have portions of different polarity, one is lipophilic and apolar, and the other one hydrophilic and polar. This type of molecules allows stabilization of colloids. There exist cationic, anionic, amphoteric or non-ionic surfactants. An example of such a surfactant is sodium citrate.

The present invention moreover discloses the use of a colloidal solution of nanoparticles for depositing nanoparticles on a support by means of an atmospheric plasma.

According to particular embodiments, the use of the colloidal solution of nanoparticles includes one or more of the following characteristics:
the colloidal solution is nebulized in the discharge or post-discharge area of atmospheric plasma;
the atmospheric plasma is generated by an atmospheric plasma torch.

The present invention also describes the use of atmospheric plasma for depositing nanoparticles on a support, said nanoparticles being in the form of a colloidal solution of nanoparticles, and said colloidal solution being nebulized at the surface of said support in said atmospheric plasma.

### SHORT DESCRIPTION OF THE FIGURES

FIG. 1 illustrates the size distribution of gold particles of a colloidal solution.

FIG. 2 illustrates an image obtained by transmission electron microscopy (TEM) of a colloidal solution of gold particles.

FIG. 3 schematically illustrates an atmospheric plasma torch.

FIG. 4 illustrates X photoelectron spectroscopy (XPS) spectra of the surface of HOPG graphite after deposition of gold nanoparticles via plasma according to the method of the present invention. (a) global spectrum, (b) deconvoluted spectrum of the Au 4f level, (c) deconvoluted spectrum of the O 1s level, (d) deconvoluted spectrum of the C 1s level.

FIG. 5 illustrates atomic force microscopy (AFM) images of a sample of HOPG graphite, a) before and b) after depositing gold nanoparticles according to the method of the present invention.

FIG. 6 illustrates images of high resolution electron microscopy of secondary electrons (Field Emission Gun Scanning Electron Microscope (FEG-SEM)) of HPOG graphite a) before, b) and c) after depositing gold nanoparticles according to the method of the present invention. (a) magnification ×2,000, (b) magnification ×25,000, (c) magnification ×80,000. Energy dispersion spectroscopic analysis (EDS) is collected on nanoparticles.

FIG. 7 illustrates the comparison of the experimental XPS spectrum of the Au 4f level shown in FIG. 4(b) and of the modeled spectrum by using a growth model of the Volmer-Weber type.

FIG. 8 illustrates an X photoelectron spectroscopy (XPS) spectrum of the surface of the HOPG graphite after depositing gold nanoparticles without using a plasma (comparative).

FIG. 9 illustrates an image obtained by high resolution electron microscopy of secondary electrons (FEG-SEM) of a HOPG graphite sample after depositing gold nanoparticles without using plasma (comparative).

FIG. 10 illustrates an image (magnification ×100,000) obtained by high resolution electron microscopy of secondary electrons (FEG-SEM) of a steel sample after depositing gold nanoparticles according to the method of the present invention.

FIG. 11 illustrates an image (magnification ×3,000) obtained by high resolution electron microscopy of secondary electrons of a glass sample after depositing gold nanoparticles (FEG-SEM) according to the method of the present invention.

FIG. 12 illustrates an image (magnification ×50,000) obtained by high resolution electron microscopy of secondary electrons (FEG-SEM) of a PVC polymer sample after depositing gold nanoparticles according to the method of the present invention.

FIG. 13 illustrates an image (magnification ×10,000) obtained by high resolution electron microscopy of secondary electrons (FEG-SEM) of an HDPE polymer sample after depositing gold nanoparticles according to the method of the present invention.

FIG. 14 illustrates an image (magnification ×10,000) obtained by high resolution electron microscopy of secondary electrons (FEG-SEM) of a steel sample after depositing gold nanoparticles, in the absence of plasma (comparative).

FIG. 15 illustrates an image obtained by transmission electron microscopy (TEM) of a sample of carbon nanotubes before (a) and after depositing gold nanoparticles according to the method of the present invention (b).

FIG. 16 illustrates an X photoelectron spectroscopy (XPS) spectrum of the surface of carbon nanotubes after depositing gold nanoparticles according to the method of the present invention.

FIG. 17 illustrates an image obtained by transmission electron microscopy (TEM) of a sample of carbon nanotubes after depositing platinum nanoparticles according to the method of the present invention.

FIG. 18 illustrates an X photoelectron spectroscopy (XPS) spectrum of the surface of carbon nanotubes after depositing platinum nanoparticles according to the method of the present invention.

FIG. 19 illustrates an image (magnification ×120,000) from high resolution electron microscopy of secondary electrons (FEG-SEM) of a HOPG graphite sample after depositing rhodium particles according to the method of the present invention.

FIG. 20 illustrates an X photoelectron spectroscopy (XPS) spectrum of the HOPG graphite surface after depositing rhodium nanoparticles according to the method of the present invention.

FIG. 21 illustrates an electron microscopy image (magnification ×100,000) of secondary electrons (FEG-SEM) of a steel sample after depositing platinum nanoparticles according to the method of the present invention.

FIG. 22 illustrates an electron microscopy image (magnification ×100,000) of secondary electrons (FEG-SEM) of a PVC sample after depositing rhodium nanoparticles according to the method of the present invention.

FIG. 23 illustrates an electron microscopy image (magnification ×100,000) of secondary electrons (FEG-SEM) of an HDPE sample after depositing rhodium nanoparticles according to the method of the present invention.

### DETAILED DESCRIPTION OF SEVERAL EMBODIMENTS OF THE INVENTION

The method for depositing nanoparticles according to the invention involves a colloidal solution or suspension of nanoparticles which is deposited on any support by means of an atmospheric plasma, said atmospheric plasma may be generated by any adequate device making use of atmospheric plasma.

This method has many advantages. For example, it allows a so-called [symbol] clean [symbol] deposit to be made, i.e. without using any so-called [symbol] polluting [symbol] solvents. Advantageously, the deposition of nanoparticles according to the invention only requires low energy consumption. Surprisingly, the deposition of nanoparticles is rapid because the activation of the support and the nebulization of the nanoparticles, also possibly the preliminary cleaning of the support, are accomplished in the atmospheric plasma, or in the flow of atmospheric plasma, in a single step or in a single continuous process.

Surprisingly, the method according to the invention allows the nanoparticles to be strongly adhered to the support. With this technique, it is possible to control the properties of the interface and to adjust the deposition of nanoparticles on the support. Further, this method does not require expensive installations and it is easily applied industrially.

The colloidal solution of nanoparticles may be prepared by any technique and/or any adequate means.

In the method according to the invention, the support, on which the colloidal solution of nanoparticles is deposited, is any adequate material which may be covered with nanoparticles, any material regardless of its nature and/or its form. Preferably, this is a solid support, gel or nanostructured material.

In the method according to the invention, the plasma is any adequate atmospheric plasma. This is a plasma generated at a pressure comprised between about 1 mbar and about 1,200 mbars, preferably between 800 and 1,200 mbars. Preferably, this is an atmospheric plasma, the macroscopic temperature of the gas of which may vary for example between room temperature and about 400° C. Preferably, the plasma is generated by an atmospheric plasma torch.

An atmospheric plasma does not require a vacuum, which makes it inexpensive and easy to maintain. With atmospheric plasma, it is possible to clean and activate the surface of the support, either by functionalizing it, for example by generating oxygen-containing, nitrogen-containing, sulfur-containing and/or hydrogen-containing groups, or by generating surface defects, for example vacancies, steps, and/or pits. These surface groups may for example comprise very reactive radicals having a short lifetime.

These reactive groups at the surface of the substrate may then react with the surface of the nanoparticles, or, with the surfactants present at their surfaces. The nanoparticles themselves may be activated by the plasma, either directly by forming radicals from the hydration water, or by reactions with a surfactant attached to the surface of the nanoparticle.

Preferably, in the method according to the invention, the activation of the support and the nebulization of the colloidal solution are accomplished concomitantly, i.e. in the plasma, or in the plasma flow, generated by a device making use of atmospheric plasma. Thus, nebulization of the colloidal solution occurs at the same time, or else immediately after the activation of the support by the atmospheric plasma.

Nebulization of the colloidal solution may be accomplished either in the discharge area or in the post-discharge area of the atmospheric plasma. Preferably, nebulization of the colloidal solution is accomplished in the post-discharge area of the plasma, since in certain cases, this may have additional advantages. With this, it is possible to not contaminate the device generating the plasma. With this, it is possible to facilitate the treatment of polymeric supports, to avoid degradation to the support to be covered and also for example to not cause melting, oxidation, degradation and/or aggregation of nanoparticles.

Nebulization of the colloidal solution is any adequate nebulization and may be accomplished in any direction (orientation) relatively to the surface of the support. Preferably, nebulization is accomplished in a direction substantially parallel to the support, but it may also be accomplished for example under an angle of about 45°, or for example under an angle of about 75°, relatively to the surface of the support to be treated.

### EXAMPLE 1

Gold nanoparticles were deposited on highly oriented pyrolytic graphite (HOPG), a support which has chemical properties similar to those of multi-walled carbon nanotubes (MWONTs).

Highly oriented pyrolytic graphite (HOPG) is commercially available (MikroMasch—Axesstech, France). With ZYB quality, this graphite, with a size of 10 mm×10 mm×1 mm, has an angle called a [symbol] mosaic spread angle [symbol] of 0.8°±0.2° and a [symbol] lateral grain [symbol] size greater than 1 mm. A few surface layers of the graphite are detached beforehand with an adhesive tape before the graphite sample is immersed in an ethanol solution for 5 minutes under ultrasonication.

The colloidal suspension is for example prepared according to the method for thermal reduction of the citrate as described in the article of Turkevich et al. J. Faraday Discuss. Chem. Soc. (1951), 11 page 55, according to the following reaction:

6HAuCl₄+K₃C₆H₅O₇+5H₂O→6Au+6CO₂+21HCl+3KCl, wherein the citrate acts as a reducing agent and as a stabilizer. Conventionally, a gold solution is prepared by adding 95 mL of an aqueous 134 mM tetrachloroauric acid solution (HAuCl₄, 3H₂O, Merck) and 5 mL of an aqueous 34 mM trisodium citrate solution (C₆H₈0₇Na₃.2H₂0, Merck) with 900 mL of distilled water. The thereby obtained solution is then brought to its boiling point for 15 minutes. With a pale yellow color, the gold solution then becomes of a red color within one to three minutes.

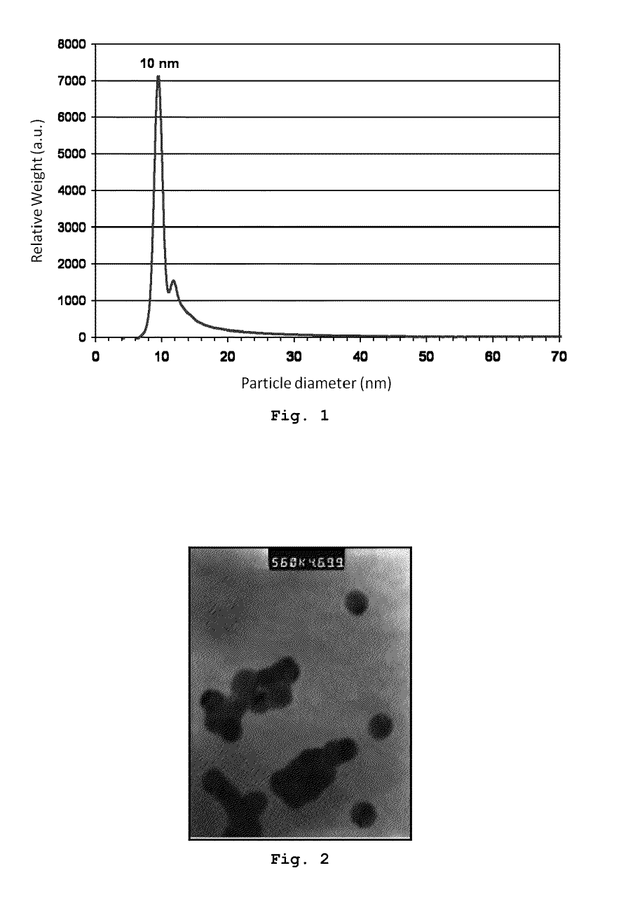

With this method for thermal reduction of the citrate, it is possible to obtain a stable dispersion of gold particles, the gold concentration of which is 134 mM, and the particles of which have an average diameter of about 10 nm and about 10% polydispersity (FIG. 1).

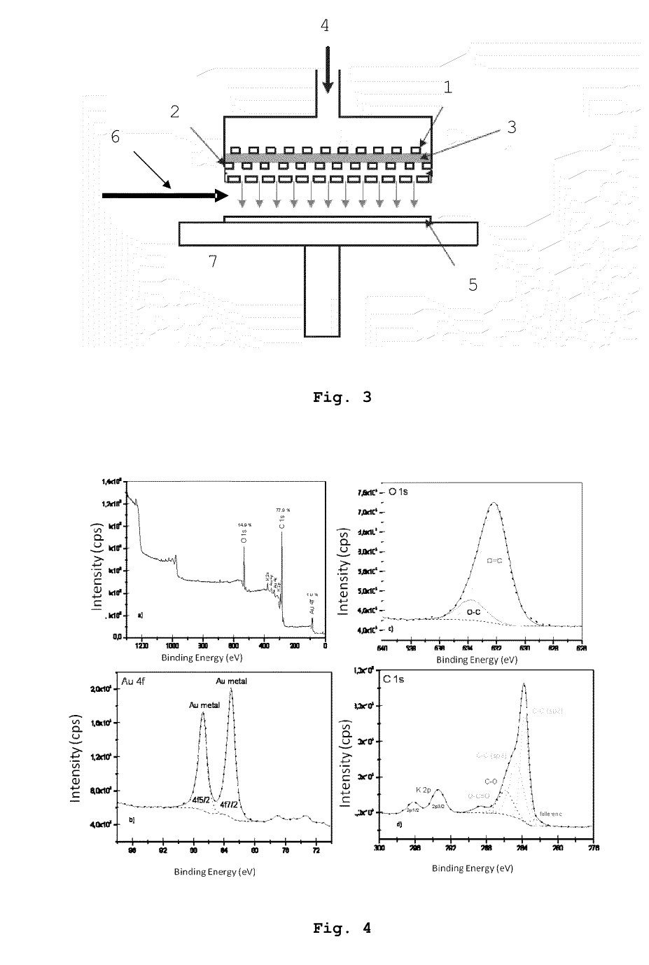

Deposition of the colloidal gold suspension on highly oriented pyrolytic graphite is carried out with a plasma source Atomflo™-250 (Surfx Technologies LLC). As described in FIG. 3, the diffuser of the plasma torch comprises two perforated aluminium electrodes, with a diameter of 33 mm, and separated by a gap with a width of 1.6 mm. In this specific example, the diffuser is placed inside a sealed chamber under an argon atmosphere at room temperature. The upper electrode 1 of the plasma source is connected to a generator of radiofrequencies, for example 13.56 MHz, while the lower electrode 2 is earthed.

The plasma torch operates at 80 W and the plasma 3 is formed by supplying the torch upstream from the electrode with argon 4 at a flow rate of 30 L/min. The space between the HOPG graphite sample 5 lying on a sample-holder 7 and the lower electrode 2 is 6±1 mm. This space is under atmospheric pressure.

Before depositing the nanoparticles, the graphite support is subject to a flow of plasma from the plasma torch, for about 2 minutes for example, which allows the support to be cleaned and activated. 3 to 5 mL of colloidal suspension is nebulized in the post-discharge area of the plasma torch and in a direction 6 substantially parallel to the sample (FIG. 3). The colloidal suspension is injected for about 5 minutes, with periodic pulses of about one second, spaced out by about 15 seconds. The samples 5 are then washed in an ethanol solution under ultrasonication for about 5 minutes.

An X photoelectron spectroscopy (XPS) analysis of the HOPG graphite surface covered with nanoparticles was carried out on a ThermoVG Microlab 350 apparatus, with an analytical chamber at a pressure of 10⁻⁹ mbars and an Al Kα X-ray source (hy=1,486.6 eV) operating at 300 W. The spectra were measured with a recording angle of 90° and were recorded with a pass energy in the analyzer of 100 eV and an X-ray beam size of 2 mm×5 mm. The determination of the chemical state, as for it, was made with a pass energy analyzer of 20 eV. The charge effects on the measured positions of the binding energy were corrected by setting the binding energy of the spectral envelope of carbon, C(1s), to 284.6 eV, a value generally recognized for accidental contamination of the carbon surface. Carbon, oxygen and gold spectra were deconvoluted by using a Shirley base line model and a Gaussian-Lorentzian model.

The XPS spectra of the surface of the HOPG graphite covered with nanoparticles are illustrated in FIG. 4. FIG. 4a) shows the presence of carbon at a percentage of 77.8%, of oxygen at a percentage of 14.9%, of potassium at a percentage of 3.2% and of gold at a percentage of 1.0%. Silica traces have also been detected; these are impurities incorporated into the HOPG graphite samples. This analysis indicates strong adhesion of gold on the HOPG graphite although the samples were washed in an ethanol solution under ultrasonication. It should be noted that with or without the ultrasonic cleaning step with ethanol, the amount of gold deposited on the HOPG graphite is similar.

The gold spectrum, Au(4f) (FIG. 4b), was deconvoluted relatively to the spin-orbit doublets Au4f5/2-Au4f7/2 with a set intensity ratio of 0.75:1 and with a separation energy of 3.7 eV. The single component Au4f7/2 is localized at 83.7 eV, which allows this to be ascribed without any ambiguity to gold metal. This means that the gold clusters have been significantly oxidized during the treatment with the plasma.

The carbon spectrum, C(1s), illustrated in FIG. 4d) comprises a main peak at 283.7 eV which is ascribed to a carbon-carbon (sp2) bond. The peaks localized at 284.6 eV, 285.8 eV and 288.6 eV may respectively be ascribed to C—C (sp3), C—O, and O—C═O bonds. The presence of observed C—O and O—C═O bonds probably originates either from the short exposure of the samples to ambient oxygen during their handling, or from the presence of a small amount of oxygen during the plasma treatment as suggested by the post-discharge characterization by optical emission spectrometry (data not shown). This explanation is consistent with the oxygen spectrum, O(1s), which shows the presence of O—C bonds (533.5 eV) and O═C bonds (531.9 eV).

The morphology of the surface of HOPG graphite covered with nanoparticles was studied by producing atomic force microscopy images recorded by a PicoSPM® LE apparatus with a Nanoscope IIIa controller (Digital Instruments, Veeco) operating under the conditions of the ambient medium. The microscope is equipped with a 25 μm analyzer and operates in contact mode. The cantilever used is a low frequency silica probe NC-AFM Pointprobe® from Nanosensors (Wetzlar-Blankenfeld, Germany) having an integrated pyramidal tip with a radius of curvature of 110 nm. The spring constant of the cantilever ranges between 30 and 70 N m⁻¹ and its measured free resonance frequency is 163.1 kHz. The images were recorded at scanning frequencies from 0.5 to 1 line per second.

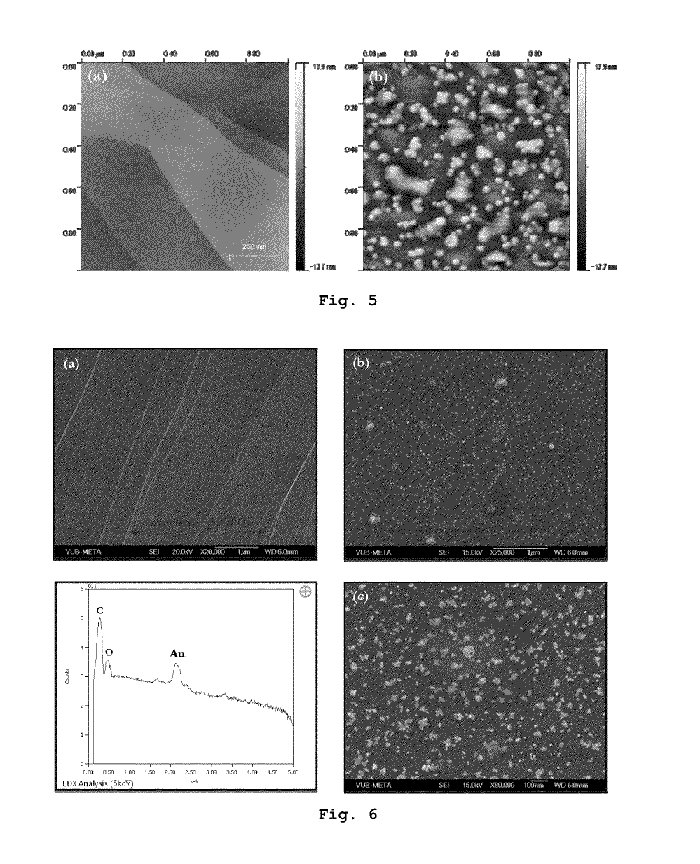

The atomic force microscopic images (1 μm×1 μm) before and after depositing the nanoparticles by plasma treatment are illustrated in FIG. 5. As shown by FIG. 5b), the graphite is covered with clusters, or islets, of gold which are either isolated and which have a diameter larger than 0.01 μm (10 nm), or branched. These islets are homogeneously dispersed with a covering rate of about 12%.

In order to confirm the nature of the islets and to obtain highly magnified images, images from scanning electron microscopy coupled with an energy dispersion X-ray spectrometer (EDS) were produced by means of a JEOL JSM-7000F apparatus equipped with a spectrometer (EDS, JED-2300F). This instrument, operating with an acceleration voltage of 15 kV and a magnification of 80,000 times, not only allows analysis of the morphology of surface structures, which may thereby be observed with optimum contrast, but also determination of the distribution of the size of the islets. Energy dispersion X-ray spectrometry analysis (EDS), as for it, allows their chemical composition to be apprehended.

Before their analysis, the graphite samples are deposited beforehand on a copper strip of a sample-holder before being introduced into the analysis chamber under a pressure of about 10⁻⁸ mbar.

As shown by FIG. 6a, in the initial state, several steps are observable with a magnification of 20,000 times. Further, as shown by FIG. 6b, many clusters, illustrated by bright spots, and having a homogeneous distribution, are present at the surface of the graphite after depositing nanoparticles according to the method of the invention. With greater magnification (80,000 times, FIG. 6c)), it is easy to perceive aggregates and isolated nanoparticles with a diameter of about 10 nm. Energy dispersion X-ray spectrometry analysis (FIG. 6d)) confirms that the bright spots are gold nanoparticles. It is also important to note that the aggregates are organized in packets of clusters of gold nanoparticles which have the same particle diameter as those of the initial colloidal suspension (FIG. 1).

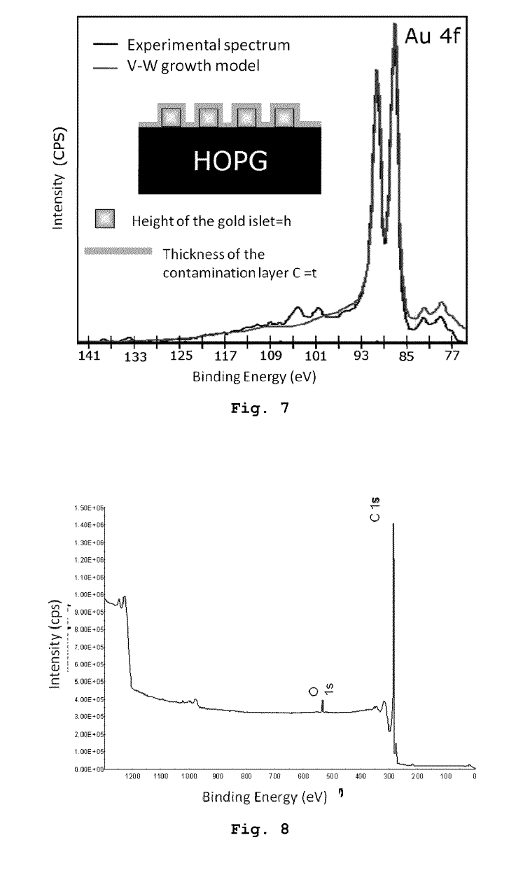

The morphology of the deposit, at a depth resolution of the order of one nanometer, was also quantified by analyzing the signal of the Au 4f peak (FIG. 7), a method proposed by Tougaard et al., in an article in J. Vac. Sci. Technol (1996) 14 page 1415.

Table 1 summarizes the characteristics of the structure of the gold islets on the HOPG graphite resulting from the analysis of three Au4f spectra with the QUASES-Tougaard software, which are expressed as a covering rate (t=thickness of the contamination C layer) and as a height of the gold islets (h). The growth mode is of the Volmer-Weber type (3D islets structure)

TABLE 1

| | Height of the | | Carbon thickness |
|---|---|---|---|
| | gold islets h | Covering | (contamination layer) |
| Samples | (nm) | percentage (%) | (nm) |
| A | 10.6 | 9.9 | 1.0 |
| B | 11.1 | 15.0 | 0.6 |
| C | 9.2 | 6.0 | 0.2 |

Surprisingly, the height of the gold islets (h) varies between 9.2 and 10.6 nm, values substantially identical with the average nanoparticle diameter of the colloidal suspension (FIG. 1). Further, it seems that about 12% of the surface of the support is covered with gold islets of about 10 nm. It should be noted that a gold covering percentage of about 10% is consistent with the covering rate as determined by atomic force microscopy and by scanning electron microscopy. Thus, the analysis of the spectral Au 4f curve with the QUASES software shows good correlation between experimental and theoretical data.

### EXAMPLE 2

### Comparative

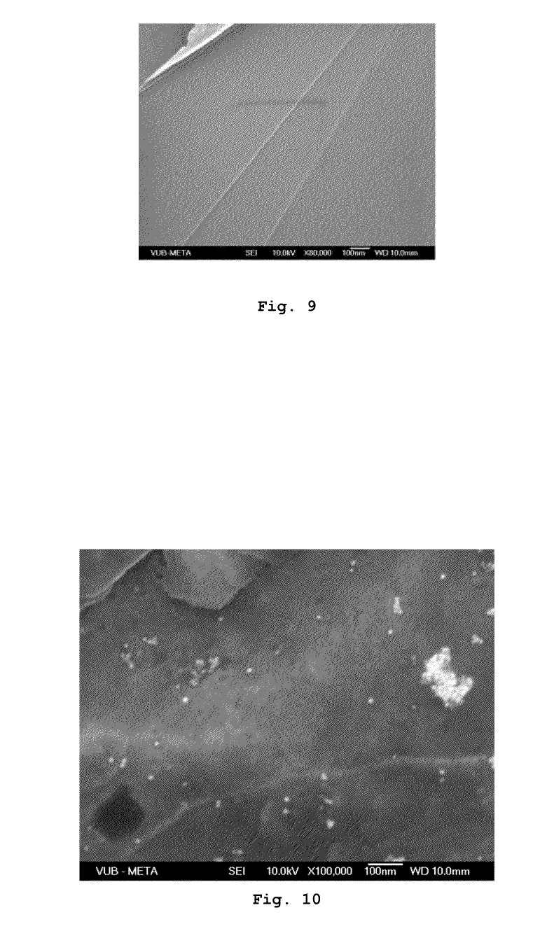

A deposition of gold nanoparticles on HOPG according to the method of Example 1 is carried out, except for the nanoparticle deposition step which is carried out without using any atmospheric plasma (FIGS. 8 and 9). After deposition of nanoparticles and before analysis, the obtained samples are washed with ethanol for about 5 minutes with ultrasonic waves.

As shown by FIG. 8, as compared with FIG. 4a, the XPS spectrum of the sample obtained after nebulization of the colloidal gold solution without using any atmospheric plasma, demonstrates the presence of carbon and oxygen and the absence of gold; this is confirmed by the atomic force microscopy image (AFM) of the relevant sample (FIG. 9 as compared with FIG. 5b or 6b).

### EXAMPLE 3

### Comparative

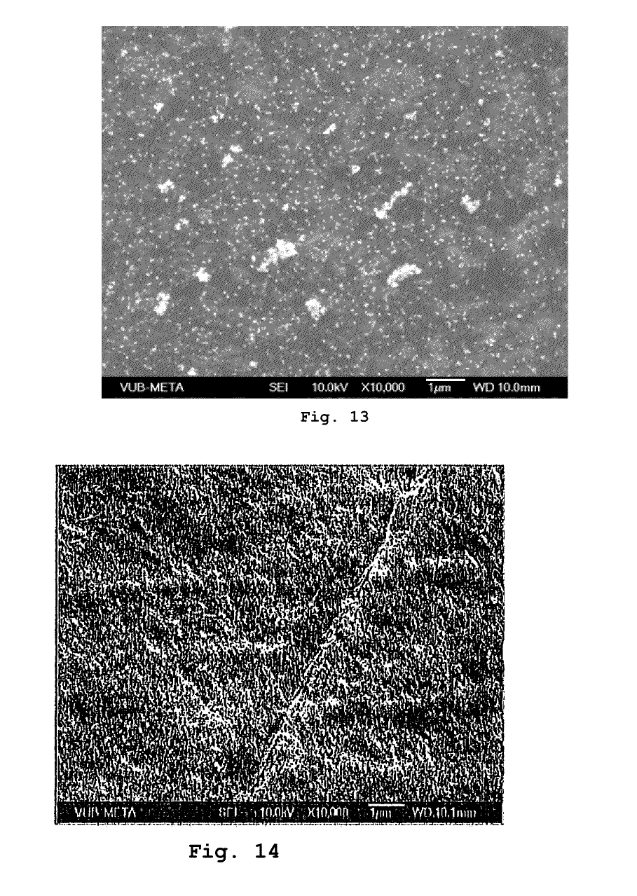

A deposition of gold nanoparticles on steel according to the method of Example 1 is carried out, except for the nanoparticle deposition step which is carried out without the use of any atmospheric plasma. After depositing the nanoparticles and before analysis, the obtained samples are washed with ethanol for about 5 minutes with ultrasonic waves. In FIG. 14, the absence of nanoparticles at the surface of the steel is noted.

In the following examples, the method used is the one described in Example 1, only the supports (substrates) used and the nature of the colloidal solutions are different.

### EXAMPLE 4

Gold nanoparticles were deposited on a steel support according to the method described in Example 1, with ultrasonic cleaning. In FIG. 10 the presence of nanoparticles is noted.

### EXAMPLE 5

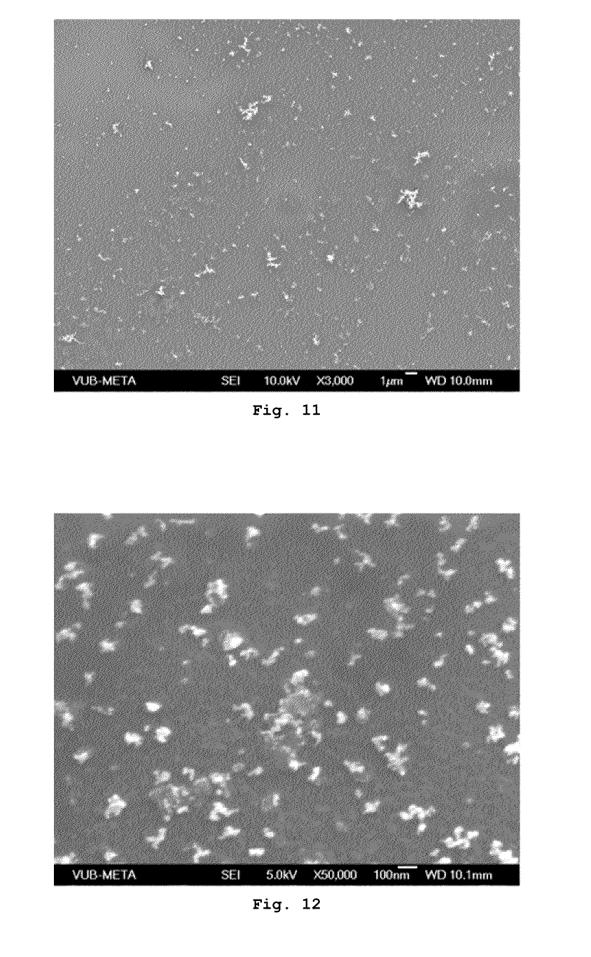

Gold particles were deposited on a glass support according to the method described in Example 1. In FIG. 11 the presence of nanoparticles after ultrasonic cleaning is noted.

### EXAMPLE 6

Gold particles were deposited on a PVC support according to the method described in Example 1, with ultrasonic cleaning. The microscopy image of FIG. 12 was obtained after having covered the sample with a metal layer. In FIG. 12 the presence of nanoparticles is noted.

### EXAMPLE 7

Gold particles were deposited on an HDPE support (FIG. 13) according to the method described in Example 1, with ultrasonic cleaning. The microscopy image of FIG. 13 was obtained after having covered the sample with a metal layer. In FIG. 13 the presence of nanoparticles is noted.

### EXAMPLE 8

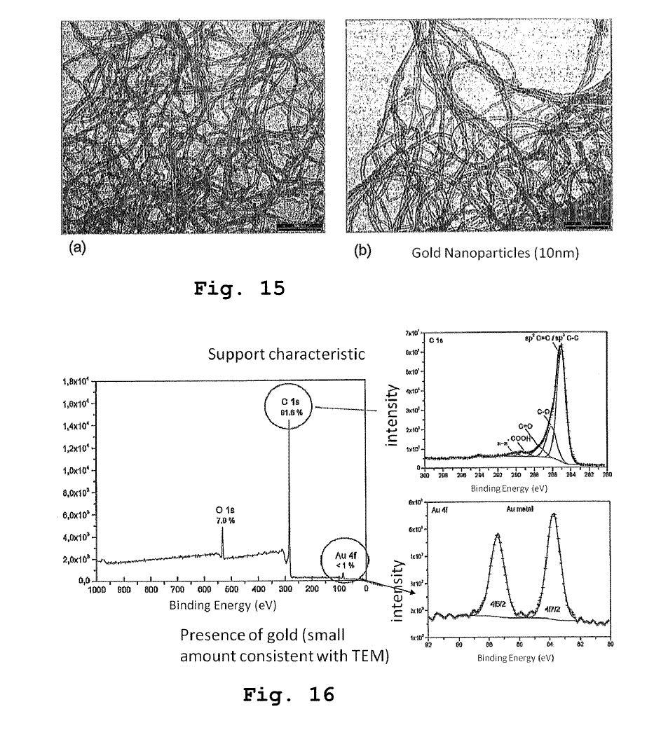

Gold nanoparticles were deposited on a carbon nanotube support according to the method described in Example 1, after ultrasonic cleaning. In FIG. 15 the presence of spherical nanoparticles of about 10 nm is noted after ultrasonic cleaning. This presence of gold is confirmed by the XPS spectrum in FIG. 16.

In the following examples, colloidal platinum and rhodium solutions provided by G. A. Somorjai (Department of Chemistry, University of California, Berkeley (USA)) were used (R. M. Rioux, H. Song, J. D. Hoefelmeyer, P. Yang and G. A. Somorjai, J. Phys. Chem. B 2005, 109, 2192-2202; Yuan Wang, Jiawen Ren, Kai Deng, Linlin Gui, and Youqi Tang, Chem. Mater. 2000, 12, 1622-1627.).

### EXAMPLE 9

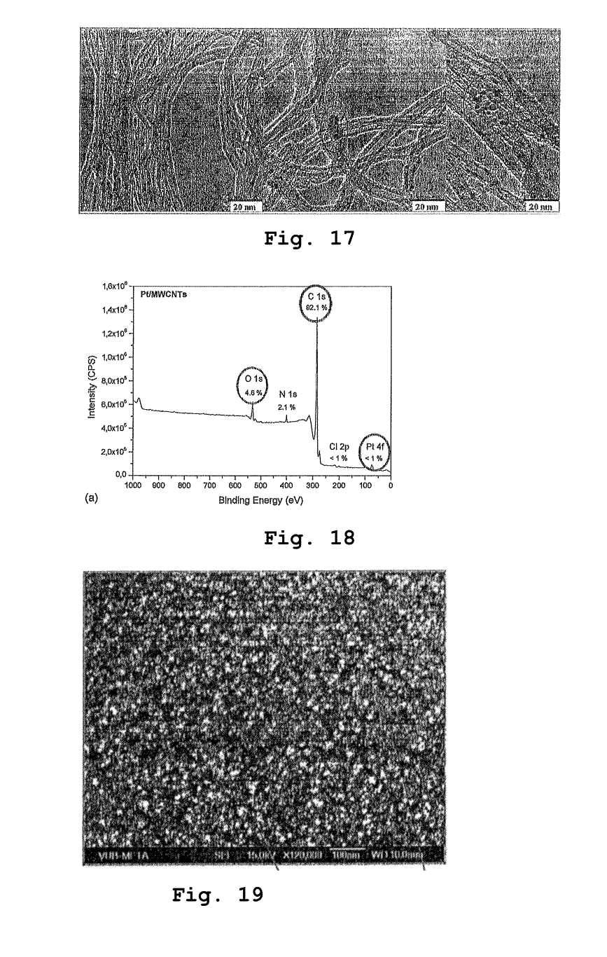

Platinum nanoparticles were deposited on a carbon nanotube support according to the method described in Example 1. In FIG. 17 the presence of spherical nanoparticles of about 10 nm is noted. This presence of platinum is confirmed by the XPS spectrum in FIG. 18.

### EXAMPLE 10

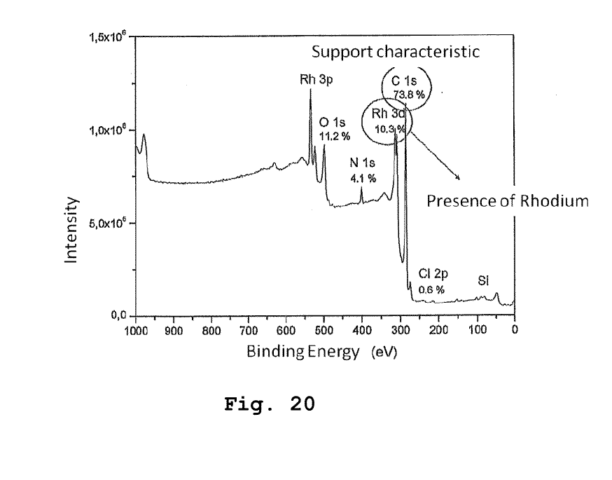

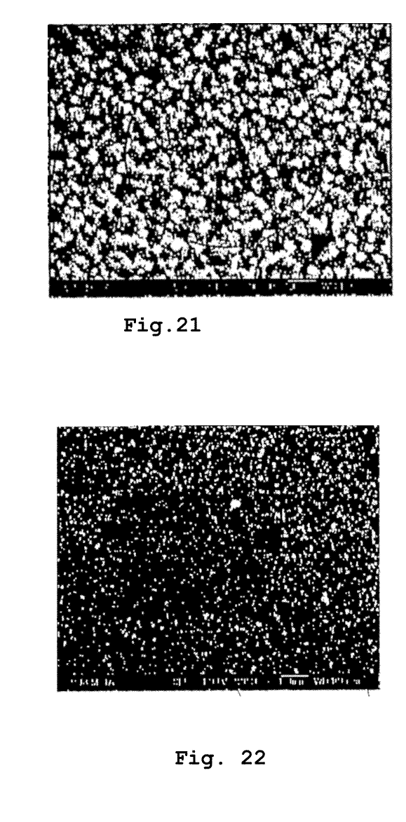

Rhodium nanoparticles were deposited on an HOPG carbon support according to the method described in Example 1. In FIG. 19, the presence of spherical nanoparticles of about 10 nm is noted after ultrasonic cleaning. This presence of rhodium is confirmed by the XPS spectrum in FIG. 20.

### EXAMPLE 11

Rhodium nanoparticles were deposited on a PVC support according to the method described in Example 1, with ultrasonic cleaning. The microscopy image of FIG. 22 was obtained after having covered the sample with a metal layer. In FIG. 22, the presence of nanoparticles is noted.

### EXAMPLE 12

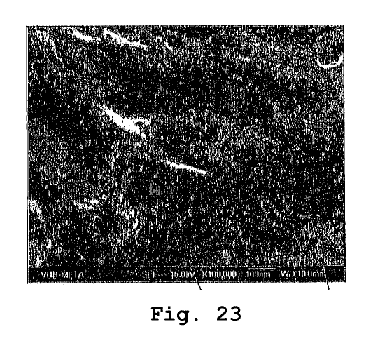

Gold nanoparticles were deposited on an HDPE support according to the method described in Example 1, with ultrasonic cleaning. The microscopy image of FIG. 23 was obtained after having covered the sample with a metal layer. In FIG. 23, the presence of nanoparticles is noted.

| | |
|---|---|
| Poids relatif (u.a.) | Relative weight (a.u.) |
| Diamètre des particules | Particle diameter |
| Intensité (CPS) | Intensity (CPS) |
| Energie de liaison (eV) | Binding energy (eV) |
| Au métal | Metal Au |
| Analyse EDX (5 keV) | EDX analysis (5 keV) |
| Spectre expérimental | Experimental spectrum |
| Modèle de croissance V-W | V-W growth model |
| Hauteur de l′îlot d′or = h | Height of the gold islet = h |
| Épaisseur de la couche de C de | Thickness of the |
| contamination = t | contamination C layer = t |
| Nanoparticules d′or (10 nm) | Gold nanoparticles (10 nm) |
| Caractéristique du support | Support characteristic |
| Présence d′or (faible quantité | Presence of gold (small |
| en accord avec TEM) | amount consistent with TEM) |
| Présence de rhodium | Presence of rhodium |

1. A method for depositing nanoparticles on a support comprising the following steps:
taking a colloidal solution or suspension of nanoparticles, and
nebulizing said colloidal solution or suspension on a surface of said support in an atmospheric plasma.

2. The method according to claim 1, wherein the atmospheric plasma is an atmospheric non-thermal plasma.

3. The method according to claim 2, wherein the plasma comprises a plasmagenic gas; the macroscopic temperature of said plasmagenic gas in said plasma may vary between −20° C. and 600° C.

4. The method according to any of the preceding claims, further comprising a step for activating the surface of the support by submitting said surface of said support to the atmospheric plasma.

5. The method according to claim 4, wherein the activation of the surface of the support and the nebulization of the colloidal solution or suspension are concomitant.

6. The method according to any of claim 4 or 5, wherein the activation of the surface of the support is preceded by cleaning of said surface of said support.

7. The method according to any of the preceding claims, wherein the step of nebulizing the colloidal solution or suspension of nanoparticles is accomplished in the discharge area or in the post-discharge area of the atmospheric plasma.

8. The method according to any of the preceding claims, wherein the plasma is generated by an atmospheric plasma torch.

9. The method according to any of the preceding claims, wherein the nebulization of the colloidal solution or suspension of nanoparticles is accomplished in a direction substantially parallel to the surface of the support.

10. The method according to any of the preceding claims, wherein the nanoparticles are nanoparticles of a metal, a metal oxide, a metal alloy or a mixture thereof.

11. The method according to any of the preceding claims, wherein the nanoparticles are nanoparticles of at least one transition metal, of its corresponding oxide, of an alloy of transition metals or of a mixture thereof.

12. The method according to any of the preceding claims, wherein the support is a solid support, gel or nanostructured material.

13. The method according to any of the preceding claims, wherein the support is selected from the group formed by a carbonaceous support, carbon nanotubes, a metal, a metal alloy, a metal oxide, a zeolite, a semiconductor, a polymer, glass and/or ceramic.

14. The method according to any of the preceding claims, wherein the atmospheric plasma is generated from a plasmagenic gas selected from the group formed by argon, helium, nitrogen, hydrogen, oxygen, carbon dioxide, air or a mixture thereof.
